(19) United States
(12) Patent Application Publication
(10) Pub. No.: US 2020/0266092 A1
(43) Pub. Date: Aug. 20, 2020

(54) APPARATUSES AND METHODS FOR NON-CONTACT HOLDING AND MEASUREMENT OF THIN SUBSTRATES

(71) Applicant: CORNING INCORPORATED, CORNING, NY (US)

(72) Inventors: Robert Dennis Grejda, Fairport, NY (US); Christopher Alan Lee, Pittsford, NY (US)

(21) Appl. No.: 16/778,478

(22) Filed: Jan. 31, 2020

Related U.S. Application Data
(60) Provisional application No. 62/807,479, filed on Feb. 19, 2019.

(51) Int. Cl. H01L 21/683; H01L 21/66; H01L 21/67; H01L 21/677

(52) U.S. Cl. CPC H01L 21/6838; H01L 22/30; H01L 21/67742; H01L 21/67092; H01L 22/12

(57) ABSTRACT

An apparatus for holding a thin substrate includes a plurality of positive pressure regions including a porous material having an upper surface and a gas flowing outward from the upper surface, the gas producing a positive pressure above the upper surface in the positive pressure regions. The apparatus includes a plurality of negative pressure regions interspersed with the plurality of positive pressure regions, the negative pressure regions exerting a holding force on a bottom surface of the thin substrate. The negative pressure regions and the positive pressure regions operate to maintain the bottom surface of the thin substrate a distance from the upper surface of the porous material in the positive pressure regions. Methods of holding a thin substrate with the apparatus are also disclosed.

This application claims the benefit of priority to U.S. Provisional Application Ser. No. 62/807,479 filed on Feb. 19, 2019, the content of which is relied upon and incorporated herein by reference in its entirety.

### BACKGROUND

### Field

The present specification generally relates to apparatuses and methods for holding thin substrates and, in particular, apparatuses and methods for non-contact holding of thin substrates for semiconductor processing.

### Technical Background

Fabrication of semiconductors involves the processing of thin substrates (i.e., wafers) having thicknesses of less than about 3 mm and diameters of less than about 450 mm. The flatness and thickness variation of the thin substrates are important to the fabrication of the micro-circuit patterns that are applied to the thin substrates in subsequent fabrication processes. Therefore, high resolution accurate measurement of the thin substrate can be an important step in the manufacture of semiconductor chips.

During fabrication of the semiconductor chips, each thin substrate is held by a chuck. According to industry standards, the thin substrate must be held in a “free state” during measurement of the thin substrate. The “free state” refers to holding the thin substrate so that no part of the chuck contacts the aperture areas of the thin substrate (e.g., the top and bottom surfaces of the thin substrate where the micro-circuit patterns and other structures are to be formed). This is because contact of the chuck with the bottom surface or top surface of the thin substrate may trap particles and/or other contaminants between the chuck and the surfaces of the thin substrate. These metal particles and/or other contaminants reduce the accuracy of flatness measurements and may damage the surfaces of the thin substrate.

### SUMMARY

Accordingly, a need exists for apparatuses and methods for holding thin substrates without contacting the top and bottom surfaces of the thin substrate. In particular, a need exists for apparatuses and methods for non-contact holding of the thin substrate that are stable enough to maintain a bottom surface of the thin substrate substantially flat to enable accurate measurement of the thickness and other attributes of the thin substrate.

According to one or more aspects of the present disclosure, an apparatus for holding a thin substrate may include a plurality of positive pressure regions comprising a porous material having an upper surface and a gas flowing outward from the upper surface, the gas producing a positive pressure above the upper surface in the positive pressure regions. The apparatus may further include a plurality of negative pressure regions interspersed with the plurality of positive pressure regions, the negative pressure regions exerting a holding force on a bottom surface of the thin substrate. The negative pressure regions and the positive pressure regions are operable to maintain the bottom surface of the thin substrate a distance D from the upper surface of the porous material in the positive pressure regions.

According to one or more other aspects of the present disclosure, a method of holding a thin substrate without contacting a bottom surface of the thin substrate may include positioning the thin substrate above an apparatus. The apparatus may include a plurality of positive pressure regions comprising a porous material having an upper surface, and a plurality of negative pressure regions interspersed with the plurality of positive pressure regions. The method may further include passing a gas into and through the porous material. The flow of the gas outward from the upper surface of the porous material may produce a gas bearing between the upper surface of the porous material and the bottom surface of the thin substrate. The method may further include applying a negative pressure to the plurality of negative pressure regions, the negative pressure exerting a holding force on the bottom surface of the thin substrate. A positive gas pressure in the positive pressure regions and the negative pressure in the negative pressure regions may be operable to maintain the bottom surface of the thin substrate a distance D from the upper surface of the porous material in the positive pressure regions.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWINGS

FIG. 1 schematically depicts a side cross-sectional view of an embodiment of an apparatus for holding a thin substrate, according to one or more embodiments shown and described herein;

FIG. 2 schematically depicts operation of a portion of the apparatus of FIG. 1 to hold the thin substrate, according to one or more embodiments shown and described herein;

FIG. 3 schematically depicts a top view of an apparatus for holding thin substrates, according to one or more embodiments shown and described herein;

FIG. 4 schematically depicts a front perspective view of the apparatus of FIG. 3 for holding thin substrates, according to one or more embodiments shown and described herein;

FIG. 5A schematically depicts another embodiment of an apparatus for holding thin substrates, according to one or more embodiments shown and described herein;

FIG. 5B schematically depicts another embodiment of an apparatus for holding thin substrates, according to one or more embodiments shown and described herein;

FIG. 6 schematically depicts a side cross-sectional view of another embodiment of an apparatus for holding thin substrates, the apparatus having an edge guide comprising a gas barrier, according to one or more embodiments shown and described herein;

FIG. 7 schematically depicts a top view of another embodiment of an apparatus for holding thin substrates, according to one or more embodiments shown and described herein; and

FIG. 8 schematically depicts a preloaded gas bearing of the apparatus of FIG. 7 for holding thin substrates, according to one or more embodiments shown and described herein.

### DETAILED DESCRIPTION

Reference will now be made in detail to embodiments of apparatuses and methods for holding a thin substrate, examples of which are illustrated in the accompanying drawings. Whenever possible, the same reference numerals will be used throughout the drawings to refer to the same or like parts. The present disclosure is directed to apparatuses and methods for holding thin substrates, such as wafers used in semiconductor manufacturing and other small thin substrates. Referring to FIG. 1, an apparatus 10 of the present disclosure for holding the thin substrates 12 is depicted. The apparatus 10 may include a plurality of positive pressure regions 20 comprising a porous material 22 having an upper surface 24 and a gas flowing outward from the upper surface 24, the gas producing a positive pressure above the upper surface 24 in the positive pressure regions 20. The apparatus 10 may further include a plurality of negative pressure regions 40 interspersed with the plurality of positive pressure regions 20, the negative pressure regions 40 exerting a holding force on a bottom surface 16 of the thin substrate 12. The positive pressure regions 20 and the negative pressure regions 40 may operate to maintain the bottom surface 16 of the thin substrate 12 a distance D from the upper surface 24 of the porous material 22 in the positive pressure regions 20. The apparatus 10 may create a preloaded gas bearing that holds the bottom surface 16 of the thin substrate 12 flat without contacting the top surface 14 or bottom surface 16 of the thin substrate 12.

Unless otherwise expressly stated, it is in no way intended that any method set forth herein be construed as requiring that its steps be performed in a specific order, nor that specific orientations be required with any apparatus. Accordingly, where a method claim does not actually recite an order to be followed by its steps, or that any apparatus claim does not actually recite an order or orientation to individual components, or it is not otherwise specifically stated in the claims or description that the steps are to be limited to a specific order, or that a specific order or orientation to components of an apparatus is not recited, it is in no way intended that an order or orientation be inferred, in any respect. This holds for any possible non-express basis for interpretation, including: matters of logic with respect to arrangement of steps, operational flow, order of components, or orientation of components; plain meaning derived from grammatical organization or punctuation, and; the number or type of embodiments described in the specification.

Directional terms as used herein—for example up, down, right, left, front, back, top, bottom—are made only with reference to the figures as drawn and the coordinate axis provided therewith and are not intended to imply absolute orientation.

As used herein, the singular forms “a,” “an” and “the” include plural referents unless the context clearly dictates otherwise. Thus, for example, reference to “a” component includes aspects having two or more such components, unless the context clearly indicates otherwise.

As used herein, the term “pitch” may refer to a shortest distance between a center of a first positive pressure region and a center of a second positive pressure region that is closest to the first positive pressure region (e.g., the distance between the centers of two adjacent positive pressure regions). The pitch may be designated with the letter P and is illustrated in FIGS. 1-3.

As used herein, the term “negative pressure” may refer to pressures that are less than atmospheric pressure. Negative pressure may be expressed as a positive value of pressure when expressed in terms of absolute pressure or as a negative value of pressure when expressed in terms of gauge pressure relative to atmospheric pressure. Negative pressure may also be expressed as a positive value of vacuum, which refers to the magnitude of the difference between atmospheric pressure and the negative pressure.

As used herein, “radial distance” may refer to a distance measured in a radial direction along a radial line extending from a center of the apparatus outward in the X-Y plane of the coordinate axis in the figures. The term “radial distance” may be used in describing one or more embodiments of the apparatus, but it is not intended to limit the shape of the apparatus to circular, cylindrical, or spherical geometries.

As previously discussed, thin substrates may be used for semiconductor chip manufacturing. These thin substrates (e.g., wafers) are thin and easily deformable, having thicknesses less than or equal to 3 mm, less than or equal to 2 mm, less than or equal to 1 mm or even less than 700 micrometers (μm). During critical fabrication steps, the thin substrate is held in a “clamped” state, i.e. with the back surface pulled optically flat to a rigid surface. These processing steps can be very sensitive to the flatness of the bottom surface of the thin substrate, which by the nature of being chucked to an optically flat surface, is the total thickness variation of the wafer (often referred to as TTV). The TTV is also critical in a series of localized ways that simulate the critical requirements of these processing steps. For this reason, it is important to be able to measure the thin substrates for their “clamped” flatness attributes. Therefore, a logical way to measure these attributes would be to “clamp” the wafer to an optically flat chuck. However, this option is not available due to semiconductor industry requirements to avoid touching the frontside (top surface) or backside (bottom surface) of the thin substrate outside of these critical processing steps, due to risk of backside micro damage, introduction of particles, or introduction of backside metal contamination on the molecular scale which have been demonstrated to impact downstream process yields.

Therefore the clamped state is typically emulated by measuring the wafer in its “free state” meaning a minimally deformed condition while only contacting the wafer at the edges. To emulate the clamped condition the thickness variation is calculated by measuring the front and backside of the wafer and constructing the thickness variation. As the requirements of the “clamped” flatness and local flatness attributes become ever tighter, the mechanical stability of the wafer during measurement becomes a critical limiting factor (vibration, acoustics, etc.) in the measurement system.

To satisfy the industry requirements for holding the thin substrate without contacting the top and bottom surfaces, devices have been developed that hold the thin substrate through 3 or more contact points at the periphery of the thin substrate, such as point contact with the outer peripheral surface of the thin substrate or contact with the top and/or bottom surfaces very close to the peripheral edges of the thin substrate. Measurement of the thin substrate then includes measuring the position for both sides of the substrate and determining the thickness variation by comparing the measurements for the top and bottom surface.

Devices utilizing 3 or more points of contact at the peripheral edges of a rigid body substrate can position the rigid body substrate with no instability in the position of the bottom surface of the substrate. However, the thin substrates for making semiconductors are not really rigid bodies and may undergo static deformation, even when held by three point contact. These thin substrates may be easily excited by vibrations from external sources, such as sound vibrations, gas movements in the clean room, or other sources vibrations, which can cause deflection of the thin substrate during measurement and processing. Instability in the 3 point contact holding device resulting in deflections of the thin substrate may result in difficulties focusing measurement and/or process equipment, such as interferometers or high-resolution microscopes, during production of the semiconductors. Thus, deflection of the thin substrate may complicate measurement of the thin substrates or fabrication of the semiconductors.

The apparatuses and methods disclosed herein solve these problems by providing a preloaded gas bearing structure capable of stably holding the thin substrate without contacting the top surface and bottom surface of the thin substrate. Referring to FIG. 1, in particular, the apparatuses 10 disclosed herein for holding a thin substrate 12 include a plurality of positive pressure regions 20 and a plurality of negative pressure regions 40 interspersed with the plurality of positive pressure regions 20. The positive pressure regions 20 may include a porous material 22 having an upper surface 24 and may have a gas flowing outward from the upper surface 24. The gas flow may produce a positive pressure above the upper surface 24 in the positive pressure regions 20. The negative pressure regions 40 interspersed with the plurality of positive pressure regions 20 may exert a holding force on the bottom surface 16 of the thin substrate 12. The positive pressure regions 20 and the negative pressure regions 40 may operate to maintain the bottom surface 16 of the thin substrate 12 a distance D from the upper surface 24 of the porous material 22 in the positive pressure regions 20. The air cushion created by the gas flow and positive pressure in the positive pressure regions 20 may prevent contact of the apparatus 10 with the bottom surface 16 of the thin substrate 12, and the holding force exerted by the negative pressure in the negative pressure regions may hold the bottom surface 16 of the thin substrate 12 proximate the upper surface 24 of the porous material 22. The combination of the positive pressure and negative pressure may make the thin substrate 12 stiff to minimize the influence of micro-vibrations on the thin substrate 12 during measurement and processing of the thin substrate 12.

The thin substrates 12 may be a small, thin, flat sheet having a top surface 14, a bottom surface 16, and a peripheral edge(s) 18. The top surface 14 may be the surface facing upward (e.g., in the +Z direction of the coordinate axis in FIG. 1), and the bottom surface 16 may be the surface facing downward (i.e., in the −Z direction of the coordinate axis in FIG. 1) towards the upper surface 24 of the porous material 22. The thin substrate 12 may be a wafer for manufacturing semiconductors, but may not be limited thereto. In some instances, the thin substrate may be a small sheet of glass for a display, or other type of substrate. The thin substrate 12 may include, but is not limited to, silicon, sapphire (Al₂O₃), silicon carbide, lithium tantalite, lithium niobate, gallium arsenide, germanium, silica (SiO₂), glass, other types of wafer materials including silica and other metal oxides, or combinations of these.

The thin substrates 12 may have thicknesses t of less than or equal to 3 millimeter (mm), less than or equal to 2 mm, less than or equal to 1 mm, or less than or equal to 0.7 mm, wherein the thickness t is measured as the distance between the bottom surface 16 and the top surface 14 of the thin substrate 12. The thickness t of the thin substrate may be greater than or equal to 0.1 mm, greater than or equal to 0.2 mm, or even greater than or equal to 0.4 mm. The thickness t of the thin substrate 12 may be from 0.1 mm to 3 mm, from 0.2 mm to 2 mm, or from 0.4 mm to 1 mm. The thin substrates 12 may have diameters less than or equal to 450 mm, less than or equal to 300 mm, or even less than or equal to 200 mm. The diameter of the thin substrates may be from 50 mm to 450 mm, or from 75 mm to 300 mm.

Referring again to FIG. 1, each of the plurality of positive pressure regions 20 may include the porous material 22 having the upper surface 24. The upper surface 24 may be a surface of the porous material 22 facing towards the thin substrate 12 (e.g., facing in the +Z direction of the coordinate axis in FIG. 1), when the thin substrate 12 is held by the apparatus 10. The porous material 22 may be a ceramic, graphite, carbon, metal, plastic, other porous material of combinations of materials. In some embodiments, the porous material 22 may be ceramic or graphite.

The porosity of the porous material 22 may be sufficient to enable the gas to flow through the porous material 22 and exit from the upper surface 24 of the porous material 22 to be distributed across the surface area of the upper surface 24. The positive pressure caused by the flowing gas may be distributed across the upper surface 24 as compared to being concentrated in a single plume, such as when gas is passed through an orifice to the upper surface 24. In this manner, the porous material 22 may cause the forces of the flowing gas against the bottom surface 16 of the thin substrate 12 to be distributed over a greater surface area, increasing the effective area over which the pressure acts against the thin substrate 12.

The porous material 22 may include a network of through pores providing a flow path through the porous material 22 to the upper surface 24 of the porous material 22. The porous material may be mesoporous (i.e., average pore size from 2 nm to 50 nm) or macroporous (i.e., average pore size greater than 50 nm). A porosity of the porous material 22 may be sufficient to allow the gas to flow through the porous material 22 to the upper surface of the porous material 22. If the porosity is too low, the gas pressure sufficient for the gas to flow through the porous material 22 may be too great. If the porosity is too high, the porosity in combination with the average pore size may limit the pitch P of the apparatus 10. The porous material 22 may have a porosity of from 10% to 60%, from 10% to 50%, from 10% to 40%, or from 10% to 25%, where the porosity can be defined as a ratio of the total pore volume to the total apparent volume of the porous material (e.g., void space as a percentage of total apparent volume).

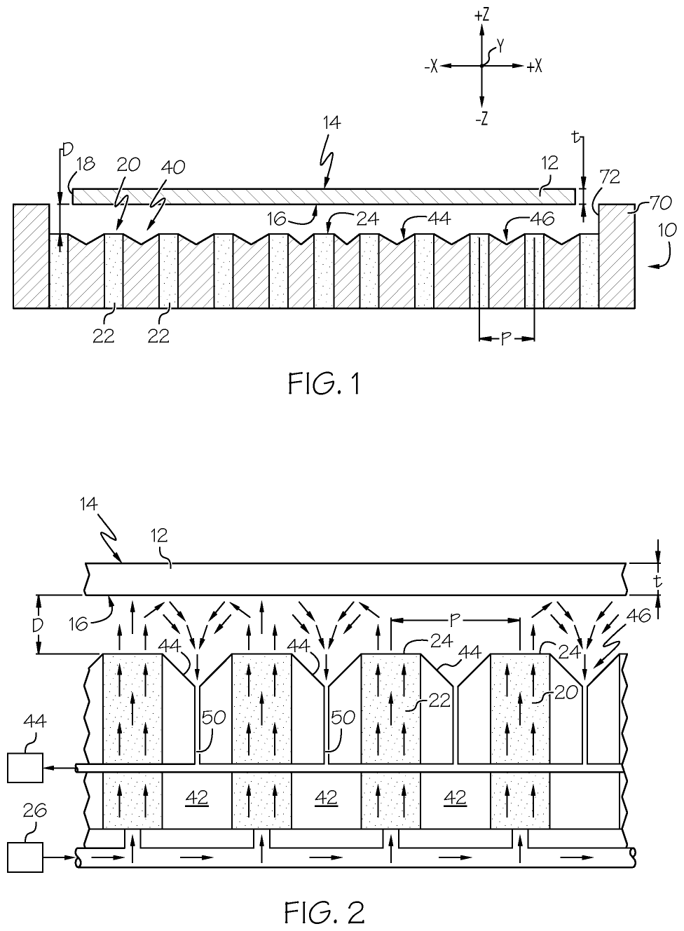

Referring to FIG. 2, the plurality of positive pressure regions 20 may include a gas source 26 in fluid communication with the porous material 22 and operable to deliver a gas into the porous material 22 at a pressure greater than atmospheric pressure, the gas flowing through the porous material 22 and out of the porous material 22 from the upper surface 24. The gas flow outward from the upper surface 24 of the porous material 22 in the positive pressure regions 20 may produce a layer of gas (e.g., a gas cushion or air bearing) between the upper surface 24 of the porous material 22 and the bottom surface 16 of the thin substrate 12. The gas flow outward from the upper surface 24 of the porous material 22 in the positive pressure regions 20 may exert a force against the bottom surface 16 of the thin substrate 12 operable to maintain the bottom surface 16 of the thin substrate 12 spaced apart from the upper surface 24 of the porous material 22 so that the apparatus 10 does not contact the bottom surface 16 of the thin substrate 12.

The pressure of the gas in the positive pressure regions 20 may be greater than or equal to 15 pounds per square inch absolute (psia) (103.4 kilopascals (kPa), where 1 psia=6.895 kPa), greater than or equal to 20 psia (137.9 kPa), or even greater than or equal to 25 psia (172.4 kPa). The pressure of the gas in the positive pressure regions 20 may be less than or equal to 80 psia (551.6 kPa), less than or equal to 75 psia (517.1 kPa), or even less than or equal to 70 psia (482.6 kPa). In some embodiments, the pressure of the gas in the plurality of positive pressure regions 20 may be from 15 psia to 80 psia. The pressure of the gas source 26 may be increased or decreased to increase or decrease the forces exerted by the gas flow on the bottom surface 16 of the thin substrate 12.

The gas passed through the porous material 22 may be a compressed gas that is free of particulates, oil, and water. As used herein, a compressed gas that is “free” of particulates, oil, and water is a compressed gas that complies with the standards for ISO 8573-1:2010 classes 0 through 6. For example, the gas may be a compressed gas having a concentration of particles with an average particle size of from 1-5 micron of less than or equal to 100,000 particles per cubic meter of compressed gas (particles/m³), less than 10,000 particles/m³, less than 1,000 particles/m³, less than 100 particles/m³, or less than or equal to 10 particles/m³. The compressed gas may have a concentration of particles with an average particle size of from 0.5 to 1 micron of less than or equal to 90,000 particles/m³, less than 6,000 particles/m³, or less than or equal to 400 particles/m³. For water, a compressed gas that is free of water may have no liquid water and may have a vapor pressure dew point of water vapor in the compressed gas of less than or equal to 10° C., less than or equal to 7° C., less than or equal to 3° C., less than or equal to −20° C., less than or equal to −40° C., or less than or equal to −70° C. For oil, the compressed gas that is free of oil may have less than 7 milligrams per cubic meter (mg/m³), less than 6 mg/m³, less than 5 mg/m³, less than 1 mg/m³, less than 0.1 mg/m³, or even less than 0.01 mg/m³. The gas may include air, carbon dioxide, or inert gases such as nitrogen, helium, argon, and other inert gases. In some embodiments, the gas may be a reactive gas that undergoes a chemical reaction upon discharge from the upper surface 24 of the porous material 22 or upon contacting the bottom surface 16 of the thin substrate 12. For example, a reactive gas may be introduced to the porous material to deposit a material on the bottom surface 16 of the thin substrate 12 through chemical vapor deposition (CVD), in which the temperature of the bottom surface 16 of the thin substrate 12 may cause the reactants in the reactant gas to undergo the chemical reaction resulting in deposition of a compound on the bottom surface 16 of the thin substrate 12.

Referring again to FIG. 1, the apparatus 10 may include a plurality of negative pressure regions 40 interspersed with the plurality of positive pressure regions 20. Each of the negative pressure regions may include a body 42 having a recessed upper surface 44 that is recessed relative to the upper surface 24 of the porous material 22 of the positive pressure regions 20. The recessed upper surface 44 may define a vacuum plenum 46 for each of the negative pressure regions 40. Thus, each of the negative pressure regions 40 may include the vacuum plenum 46 defined by the recessed upper surface 44. The vacuum plenum 46 of each of the negative pressure regions 40 may be a channel or a recessed groove.

Referring to FIG. 2, the apparatus 10 may include a negative pressure source 48 fluidly coupled to the plurality of negative pressure regions 40. The negative pressure source 48 may be operable to maintain each of the plurality of negative pressure regions 40 at a pressure less than atmospheric pressure, the negative pressure exerting a holding force on the bottom surface 16 of the thin substrate 12. The negative pressure source 48 is not particularly limited and may include any device or system capable of producing a negative pressure in the negative pressure regions 40. Examples of negative pressure sources 48 may include, but are not limited to vacuum pumps, Venturi devices (e.g., vacuum ejectors), or other vacuum producing devices or systems.

The holding force exerted by the negative pressure in the negative pressure regions 40 may be opposite in direction to the force applied by the positive pressure regions. The negative pressure in the negative pressure regions 40 may be a function of the stiffness or rigidity of the thin substrate 12. The negative pressure regions 40 may have a pressure less than atmospheric pressure, such as less than 14 psia (96.5 kPa), less than or equal to 12 psia (82.7 kPa), or even less than or equal to 10 psia (68.9 kPa). The negative pressure regions 40 may have a pressure greater than or equal to 2 psia (13.8), greater than or equal to 4 psia (27.6 kPa), or even greater than or equal to 6 psia (41.4 kPa). In some embodiments, the negative pressure may be from 2 psia to less than 15 psia, from 2 psia to 14 psia, from 4 psia to 12 psia, or from 6 psia to 10 psia. The negative pressure in the negative pressure regions 40 may be sufficient to planarize the bottom surface 16 of the thin substrate 12 to the same flatness of the upper surfaces of the apparatus 22. The upper surfaces of the apparatus 10 may be optically flat or may be characterized by a flatness which is known to be transferred to the thin substrate 12 when the thin substrate 12 is held or “clamped” by the apparatus 10.

The negative pressure may be increased or decreased (e.g., decreasing or increasing the pressure) in the negative pressure regions 40 to increase or decrease the holding force exerted by the negative pressure on the bottom surface 16 of the thin substrate 12. In some embodiments, a single negative pressure applied at all of the negative pressure regions 40 may be increased or decreased to manipulate the flatness of the bottom surface 16 of the thin substrate. Alternatively or additionally, in some embodiments, the negative pressure in one or more of the negative pressure regions 40 may be independently controlled so that the negative pressure in certain regions can be adjusted to further flatten the bottom surface 16 of the thin substrate 12.

Referring to FIG. 2, as previously discussed, each of the plurality of negative pressure regions 40 may include the vacuum plenum 46 defined by the recessed upper surface 44 of the body 42. The negative pressure source 48 may be fluidly coupled to the vacuum plenum 46 of each of the plurality of negative pressure regions 40. In some embodiments, the negative pressure source 48 may be fluidly coupled to the vacuum plenum 46 of each of the plurality of negative pressure regions 40 by a passage or conduit 50. The conduit 50 may pass through the body 42 of the negative pressure regions 40. Alternatively or additionally, in some embodiments, the negative pressure source 48 may be directly fluidly coupled to the vacuum plenum 46 of each of the plurality of negative pressure regions 40, such as being fluidly coupled to each of the vacuum plenums 46 at a lateral side of the vacuum plenum 46.

In some embodiments, the body 42 of the negative pressure regions 40 may be a non-porous material that does not allow gases to permeate through the body 42. The bodies 42 of the negative pressure regions 40 may be interspersed with (e.g., alternated with) the porous material 22 of the positive pressure regions 20 to produce the alternating pattern of positive pressure regions 20 and negative pressure regions 40. In some embodiments, the body 42 may be made from the same porous material 22 as the positive pressure regions and a coating may be applied to the recessed upper surface 44 of the body 42 in the negative pressure regions 40 to prevent gas flow from the porous material 22 of the positive pressure regions 20 into the vacuum plenums 46 of the negative pressure regions 40. The coating may be an impermeable coating that does not allow passage of light gases, such as nitrogen, air, carbon dioxide, helium, or other light gases, through the coating. In some embodiments, the negative pressure regions 40 may include the porous material and an impermeable coating applied to the upper surface of the porous material, and each of the negative pressure regions 40 may be fluidly coupled to the negative pressure source 48 through the conduit 50 passing through the porous material and the impermeable coating.

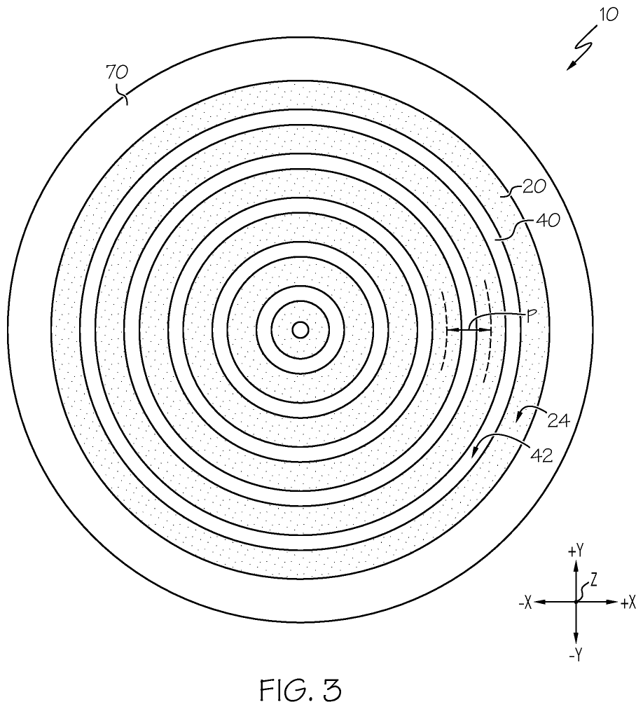

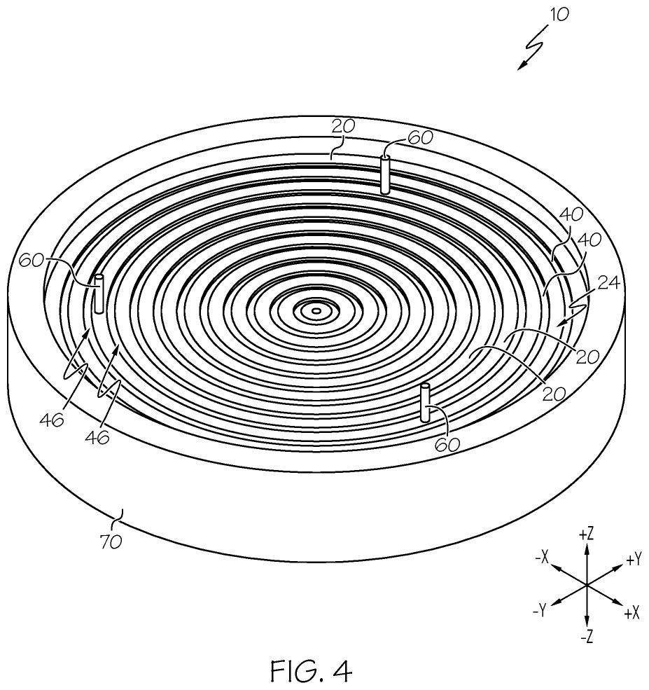

Referring to FIGS. 3 and 4, the apparatuses 10 disclosed herein may include an alternating pattern of the positive pressure regions 20 and the negative pressure regions 40. In some embodiments, each of the plurality of negative pressure regions 40 may be disposed between two of the positive pressure regions 20. In some embodiments, each of the plurality of positive pressure regions 20 may be disposed between two of the negative pressure regions 40. The alternating positive pressure regions 20 and negative pressure regions 40 may be contained within a housing 70 that surrounds the outermost positive pressure region 20 or negative pressure region 40.

In some embodiments, the apparatus 10 may include alternating portions of the porous material 22 for the positive pressure regions 20 and portion of a non-porous material for the negative pressure regions 40, which produce the alternating pattern of positive pressure regions 20 and negative pressure regions 40. The non-porous material may be generally non-permeable to gases, such as air, nitrogen, carbon dioxide, or other gases. In some embodiments, the positive pressure regions 20 and the negative pressure regions 40 may be made from the same porous material 22, and the negative pressure regions 40 may include the impermeable coating on the recessed upper surface 44 to prevent gases flowing from the porous material 22 in the positive pressure regions 20 out from the recessed upper surface 44 in the negative pressure regions 40.

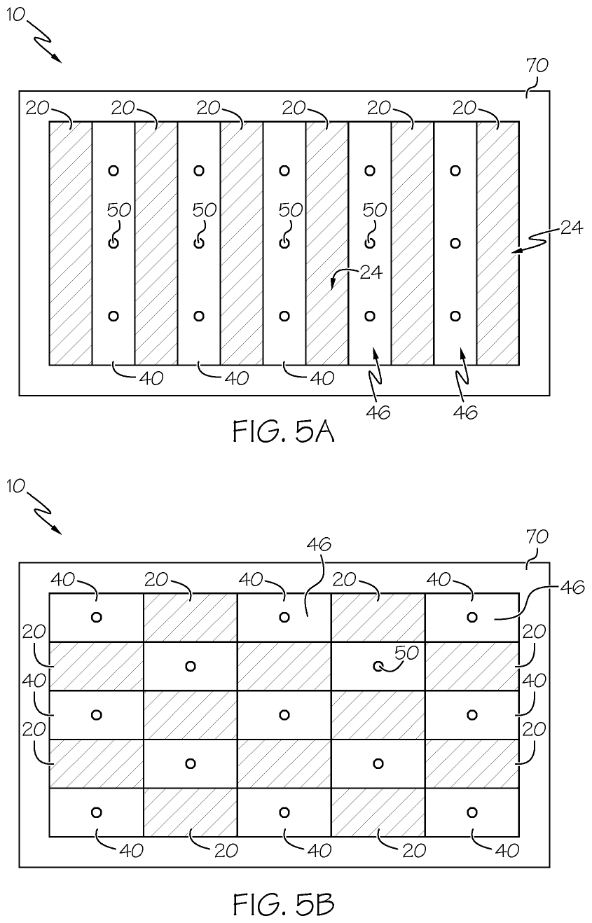

Referring to FIG. 3, in some embodiments, the apparatus 10 may be circular in shape such that the alternating positive pressure regions 20 and negative pressure regions 40 comprise alternating concentric annular regions or rings. Although depicted in FIGS. 3 and 4 as having a circular shape, the apparatuses 10 disclosed herein may not be limited to circular shapes. Suitable shapes for the apparatus 10 may also include, but are not limited to, square, rectangular, polygonal, ovoid, irregular shapes, or other shapes. Referring now to FIG. 5A, in some embodiments, the apparatus 10 may have an overall shape that is square or rectangular, and the positive pressure regions 20 and negative pressure regions 40 may be rectangular strips extending across a width of the apparatus 10. Referring to FIG. 5B, in some embodiments, the apparatus 10 may have an overall shape that is rectangular or square, and the positive pressure regions 20 and negative pressure regions 40 may be alternating rectangular or square regions forming a grid pattern. Other arrangements and patterns of the positive pressure regions 20 and negative pressure regions 40 are contemplated.

The apparatus 10 may have a size that is sufficient to hold the thin substrate 12. In some embodiments, the apparatus 10 may have a size sufficient to hold a plurality of thin substrates 12. The apparatus 10 may have a largest outer dimension of the alternating pattern of positive pressure regions and negative pressure regions 40 of greater than or equal to 5 mm, greater than or equal to 10 mm, or greater than or equal to 50 mm. The apparatus 10 may have the largest outer dimension of the alternating pattern of positive pressure regions and negative pressure regions 40 that is less than or equal to 300 mm, less than or equal to 250 mm, or less than or equal to 200 mm. The apparatus 10 may have the largest outer dimension of the alternating pattern of positive pressure regions 20 and negative pressure regions 40 of from 5 mm to 300 mm, from 10 mm to 250 mm, or from 50 mm to 200 mm.

Referring again to FIGS. 1-3, the alternating pattern of positive pressure regions 20 and negative pressure regions 40 may be characterized by the pitch P, which is a distance measured from a center of a first positive pressure region 20 to a center of a second positive pressure region 20, which is the positive pressure region 20 closest to the first positive pressure region. Referring to FIG. 3, for example, the pitch P may be radial distance between two adjacent positive pressure regions 20.

The pitch P of the apparatus 10 may be small enough to reduce a magnitude of variability in the flatness of the bottom surface 16 of the thin substrate 12 to less than or equal to 75 nanometers (nm), less than or equal to 50 nm, less than or equal to 20 nm, less than or equal to 10 nm, less than or equal to 5 nm, less than or equal to 2 nm, or even less than or equal to 1 nm. If the pitch P of the apparatus 10 is too large, the magnitude of the variability in the flatness of the bottom surface 16 of the thin substrate 12 may be large enough to produce measurement and production errors during processing of the thin substrate 12. In some embodiments, the apparatus 10 may have a pitch P of less than or equal to 20 mm, less than or equal to 10 mm, less than or equal to 5 mm, less than or equal to 2 mm, less than or equal to 1 mm, or even less than or equal to 500 μm, wherein the pitch P is measured from the center of a first positive pressure region 20 to the center of a second positive pressure region 20 that is closest to the first positive pressure region 20. The thickness t and rigidity of the thin substrate 12 may determine the pitch P that enables the apparatus 10 to produce the target variability in the flatness of the bottom surface 16 of the thin substrate 12.

Referring to FIG. 4, the apparatus 10 may include at least one edge guide 60 positioned to restrict movement of the thin substrate 12 in a plane parallel to the bottom surface 16 of the thin substrate 12 when the thin substrate 12 is held by the apparatus 10. The edge guides 60 may be operable to prevent the thin substrate 12 from moving laterally (i.e., in the X-Y plane of the coordinate axis in FIG. 4). The edge guides 60 may include physical barriers, electrostatic barriers, or gas barriers operable to restrict lateral movement of the thin substrate 12.

Referring to FIG. 4, in some embodiments, the edge guides 60 may include one or more physical barriers, such as pins or blocks, extending upward (i.e., in the +Z direction of the coordinate axis of FIG. 4) from the upper surfaces 24 of the positive pressure regions 20 and/or recessed upper surfaces 44 of the negative pressure regions 40. Physical barriers may restrict lateral movement of the thin substrate 12 through contact of the physical barriers with the peripheral edges 18 of the thin substrate 12. Contact of the edge guides 60 with the peripheral edges 18 of the thin substrate 12 may be constant or transient. Constant contact of the edge guides 60 with the peripheral edges 18 of the thin substrate 12 may maintain the thin substrate 12 in a fixed position in the X-Y plane of the coordinate axis in FIGS. 1-4. Transient contact of the edge guides 60 with the peripheral edges 18 of the thin substrate 12 may enable some limited lateral movement of the thin substrate 12, but restrict lateral movement beyond this limited movement. With transient contact, the edge guides 60 may contact the peripheral edges 18 of the thin substrate 12 only when lateral movement of the thin substrate 12 brings the peripheral edge 18 into contact with the edge guides 60.

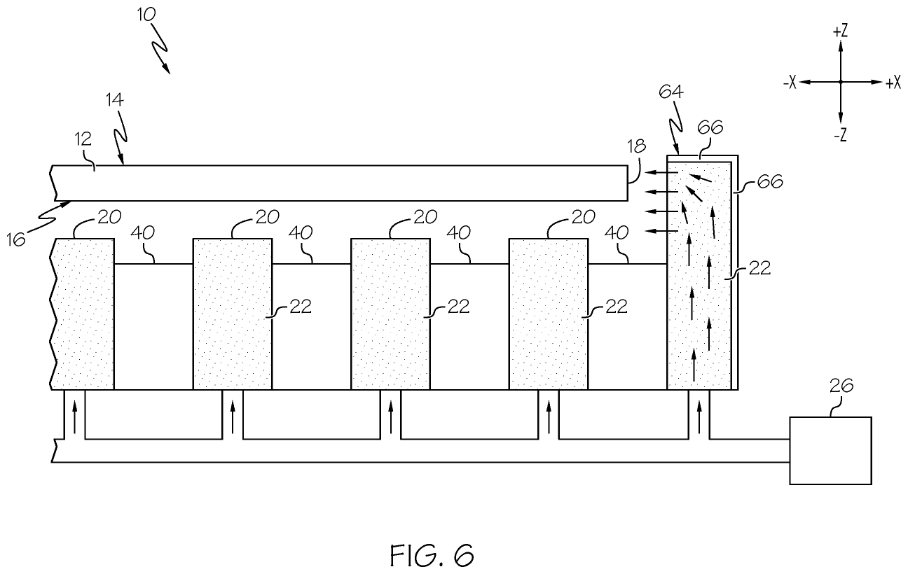

Referring to FIG. 1, in some embodiments, the edge guides 60 may include at least a portion of the inner surfaces 72 of the housing 70 that surrounds the positive pressure regions 20 and negative pressure regions 40. In some embodiments, the apparatus 10 may include a plurality of edge guides 60, such as 3, 4, 5, 6, or more than 6 edge guides 60. In some embodiments, the edge guides 60 may include an electrostatic barrier or a gas barrier operable to restrict or prevent lateral movement of the thin substrate 12 held by the apparatus 10. For example referring to FIG. 6, the apparatus 10 may include edge guides 60 comprising at least one edge guide positive pressure region 64 extending vertically upward (i.e., in the +Z directions of the coordinate axis in FIG. 6) from the alternating pattern of positive pressure regions 20 and negative pressure regions 40. The edge guide positive pressure region 64 may include the porous material 22 and may be fluidly coupled to the gas source 26. The edge guide positive pressure region 64 may be configured to direct the gas laterally towards the peripheral edges 18 of the thin substrate 12 (e.g., in the −X direction of the coordinate axis of FIG. 6). The edge guide positive pressure region 64 may include an impermeable layer 66 on one or more surface of the edge guide positive pressure region 64 to prevent gas flow from exiting from these surfaces and to direct the gas flow towards the peripheral edge 18 of the thin substrate 12. The gas flow from the edge guide positive pressure region 64 may produce a gas barrier that restricts or prevents lateral movement of the thin substrate 12. In some embodiments, the apparatus 10 may also include one or more edge guide negative pressure regions (not shown) interspersed with the edge guide positive pressure regions 64 to produce an alternating pattern of edge guide positive pressure regions 64 and edge guide negative pressure regions. The alternating pattern of the edge guide may alternate between edge guide positive pressure regions 64 and edge guide negative pressure regions with respect to the vertical direction (i.e., in the +/−Z direction of FIG. 6), the horizontal direction (i.e., with respect to the X-Y plane of the coordinate axis of FIG. 6), or both. Other methods of restricting lateral movement of the thin substrate 12 are also contemplated.

Referring again to FIG. 2, operation of the apparatus 10 to hold the thin substrate 12 may include introducing the gas to the porous material 22 in the positive pressure regions 20 and introducing the negative pressure to the vacuum plenum 46 of the negative pressure regions 40. The thin substrate 12 may be placed in the apparatus 10 (e.g., placed proximate the upper surface 24 of the porous material 22 of the apparatus 10). In the positive pressure regions 20, the gas may flow into and through the porous material 22, exiting from the porous material 22 through the upper surface 24, as shown by the upward pointing arrows in FIG. 2. The porous material 22 may distribute the gas flow across the at least a portion of the surface area of the upper surface 24 of the porous material 22. In some embodiments, the porous material 22 may distribute the gas flow across the entire surface area of the upper surface 24. The gas flow exiting the upper surface 24 of the porous material 22 in the positive pressure regions 20 may exert forces against the bottom surface 16 of the thin substrate 12. Thus, the positive pressure regions 20 may produce a gas cushion between the upper surface 24 of the porous material 22 and the bottom surface 16 of the thin substrate 12, thereby preventing contact of the upper surface 24 of the porous material 22 and the bottom surface 16 of the thin substrate 12. The positive gas pressure in the positive pressure regions 20 may result in no part of the apparatus 10 contacting the top surface 14 or the bottom surface 16 of the thin substrate 12.

The negative pressure applied to the vacuum plenum 46 in the negative pressure regions 40 may exert a suction force against the bottom surface 16 of the thin substrate 12. The suction force may be a holding force that operates to pull the thin substrate 12 towards the apparatus 10. The holding force vector may have an average direction opposite the direction of the vector of the force exerted by the gas flow against the bottom surface 16 in the positive pressure regions 20. The holding force and the force exerted by the gas flow may balance each other at a distance D, which is the distance measured between the upper surface 24 of the porous material 22 and the bottom surface 16 of the thin substrate 12. The alternating positive gas pressure in the positive pressure regions 20 and the negative pressure in the negative pressure regions 40 operate to maintain the bottom surface 16 of the thin substrate 12 the distance D from the upper surface 24 of the porous material 22 in the positive pressure regions 20.

The positive pressure regions 20 and negative pressure regions 40 may cooperate to hold the thin substrate 12 rigid with the bottom surface 16 maintained the distance D from the upper surface 24 of the porous material 22. The positive pressure regions 20 and the negative pressure regions 40 may cooperate to maintain the bottom surface 16 of the thin substrate 12 substantially flat. Substantially flat may refer to the flatness of the bottom surface 16 of the thin substrate 12 within a tolerance of less than or equal to 75 nm, less than or equal to 50 nm, less than or equal to 20 nm, less than or equal to 10 nm, less than or equal to 5 nm, less than or equal to 2 nm, or even less than or equal to 1 nm. In other words, the magnitude of variation in the distance D from the upper surface 24 of the porous material 22 to the bottom surface 16 of the thin substrate 12 may be less than or equal to 75 nm, less than or equal to 50 nm, less than or equal to 20 nm, less than or equal to 10 nm, less than or equal to 5 nm, less than or equal to 2 nm, or even less than or equal to 1 nm. Thus, the apparatuses 10 disclosed herein may be operable to maintain the bottom surface 16 of the thin substrate 12 flat to within a tolerance having a magnitude less than or equal to 75 nm, less than or equal to 50 nm, less than or equal to 20 nm, less than or equal to 10 nm, less than or equal to 5 nm, less than or equal to 2 nm, or even less than or equal to 1 nm. The apparatuses 10 disclosed herein may reduce or control localized deflections of the thin substrate 12 to an acceptable level.

Maintaining the bottom surface 16 of the thin substrate 12 substantially flat may enable the thickness variation of the thin substrate 12 to be determined by measuring only the location/position of the top surface 14 of the thin substrate 12. Thus, the apparatus 10 disclosed herein may simplify inspection the thin substrates 12 prior to processing steps. Additionally, maintaining the thin substrate 12 rigid and stiff may reduce or eliminate the influence of micro-vibrations on the position of the top surface 14 of the thin substrate 12, thereby enabling improved resolution during lithographic processes in the manufacture of semiconductors, such as those used to make micro-circuits.

The stiffness of the thin substrate 12 may be increased or decreased by increasing or decreasing, respectively, the pressure of gas in the positive pressure regions 20 and the vacuum in the negative pressure regions 40. For example, the stiffness of the thin substrate 12 may be increased by increasing the gas pressure in the positive pressure regions 20 and increasing the vacuum (i.e., further reducing the pressure) in the negative pressure regions 40. Increasing the stiffness of the thin substrate 12 may increase the flatness of the bottom surface 16 of the thin substrate (i.e., decrease the magnitude in variations in the flatness of the bottom surface 16). Thus, the magnitude in the variations in flatness of the bottom surface 16 of the thin substrate 12 may be reduced by increasing the stiffness by increasing the gas pressure in the positive pressure regions 20 and increasing the vacuum in the negative pressure regions 40.

The distance D between the upper surface 24 of the porous material 22 and the bottom surface 16 of the thin substrate 12 may be increased or decreased by changing the magnitude of the gas pressure in the positive pressure regions 20 relative to the vacuum in the negative pressure regions 40. For example, the distance D may be increase by increasing the gas pressure in the positive pressure regions 20 while maintaining the vacuum in the negative pressure regions 40 constant or by increasing the vacuum (i.e., decreasing the pressure) in the negative pressure regions 40 while maintaining the gas pressure in the positive pressure regions 20 constant. The distance D may be referred to as the “ride height” of the thin substrate 12 above the apparatus 10. The distance D may be greater than or equal to 1 μm, greater than or equal to 5 μm, greater than or equal to 10 μm, or greater than or equal to 15 μm. The distance D may be less than or equal to 50 μm, less than or equal to 40 μm, less than or equal to 35 μm, or even less than or equal to 30 μm.

In some embodiments, the distance D may be locally controlled by independently controlling the gas pressure in one or more of the plurality of positive pressure regions 20 relative to the other positive pressure regions or by independently controlling the vacuum in one or more of the plurality of negative pressure regions 40 relative to the vacuum in the other of the negative pressure regions 40. In other words, gas pressure in each of the positive pressure regions 20 and/or the vacuum in each of the negative pressure regions 40 may be independently controlled to provide localized control of the distance D. Localized control of the gas pressure in the positive pressure regions 20 and/or vacuum pressure in the negative pressure regions 40 may enable the apparatus 10 to accommodate thin substrates 12 that are warped or to purposely form the thin substrates 12 into various contoured shapes.

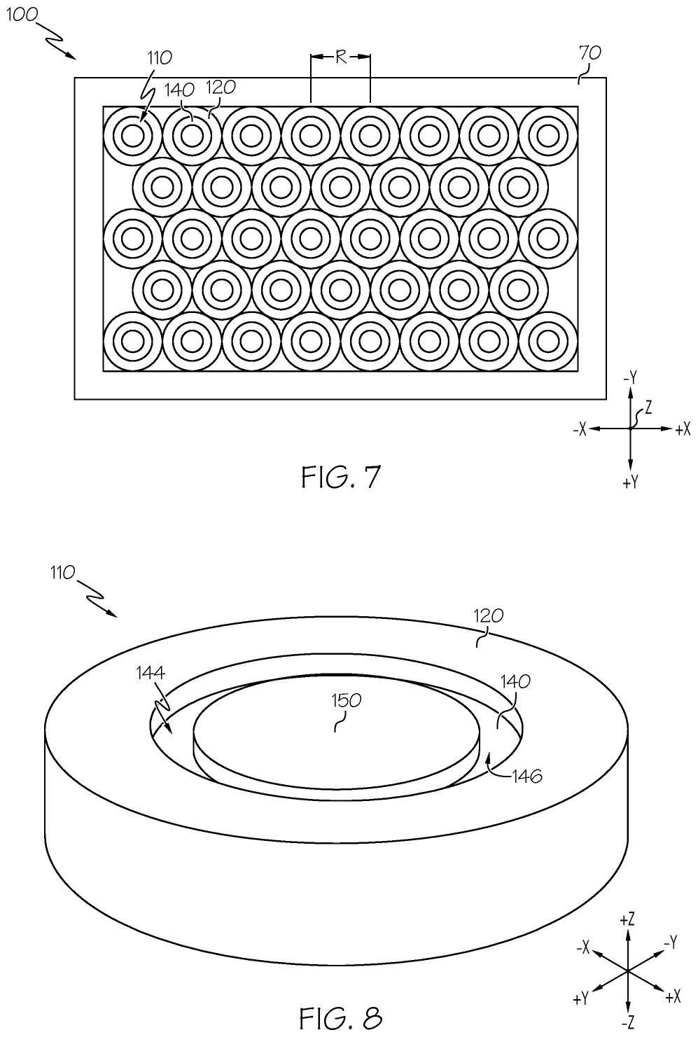

Referring to FIG. 7, an apparatus 100 disclosed herein may include a plurality of preloaded gas bearings 110 arranged in an array. The array of preloaded gas bearings 110 may be contained within the housing 70. Referring to FIG. 8, each of the preloaded gas bearings 110 may include a single positive pressure region 120 and a single negative pressure region 140. The preloaded gas bearings 110 may also include a central region 150. The single positive pressure region 120 may include the porous material 22, which may have any of the properties and characteristics previously described herein for porous material 22. The single positive pressure region 120 may be fluidly coupled to a gas source operable to introduce a gas into the porous material 22. The gas and gas source may have any of the properties and/or characteristics previously described herein for the gas and gas source 26.

The single negative pressure region 140 of the preloaded gas bearing 110 may have any other properties and characteristics previously described for the negative pressure regions 40 of apparatus 10. For example, the single negative pressure region 140 may include a plenum 146 defined by an upper surface 144. The plenum 146 may be an annular channel as depicted in FIG. 8. The single negative pressure region 140 may include a body portion comprising a porous material or non-porous material. When the body portion of the single negative pressure region 140 is a porous material (e.g., porous material 22), the single negative pressure region 140 may include an impermeable layer disposed on the upper surface 144 of the body portion to prevent gas from passing through the body portion and outward from the upper surface 144. The single negative pressure region 140 may include a negative pressure source fluidly coupled to the plenum 146. The negative pressure source may have any of the properties or characteristics previously described herein for negative pressure source 48.

Each of the preloaded gas bearings 110 may have a largest outer dimension less than or equal to 5 mm, such as less than 2 mm, or even less than 1 mm. Referring to FIG. 7, the preloaded gas bearings 110 may have dimensions small enough to provide the apparatus 100 with a center-to-center distance R of less than 5 mm, less than 2 mm, less than 1 mm, or even less than 0.5 mm. The center-to-center distance R of the apparatus 100 may be a distance between the centers of two adjacent preloaded gas bearings 110 of the apparatus 100 and may be indicative of the spacing of the single positive pressure regions 120 and single negative pressure regions 140 of adjacent preloaded gas bearings 110 for the apparatus 100. Operation of the apparatus 100 may be the same or similar to operation of the apparatus 10 previously described herein.

Referring again to FIG. 1, a method of holding the thin substrate 12 without contacting the bottom surface 16 of the thin substrate 12 may include positioning the thin substrate 12 above the apparatus 10. The methods disclosed herein will be described in reference to apparatus 10 depicted in FIG. 1 for convenience. However, it is understood that the methods disclosed herein may be performed using apparatus 100 as well. The apparatus 10 may include the plurality of positive pressure regions 20, which may include the porous material 22 having upper surface 24. The apparatus 10 may also include the plurality of negative pressure regions 40 interspersed with the plurality of positive pressure regions 20. The positive pressure regions 20 and negative pressure regions 40 may have any features previously discussed herein for the positive pressure regions 20 and negative pressure regions 40. The method may further include passing a gas into and through the porous material 22. The flow of gas may exit the porous material 22 outward from the upper surface 24 of the porous material 22 to produce a gas bearing (e.g., gas cushion) between the upper surface 24 of the porous material 22 and the bottom surface 16 of the thin substrate 12. The method may further include applying a negative pressure to the plurality of negative pressure regions 40, the negative pressure exerting a holding force on the bottom surface 16 of the thin substrate 12. The alternating positive gas pressure in the positive pressure regions and negative pressure in the negative pressure regions operate to maintain the bottom surface 16 of the thin substrate 12 the distance D from the upper surface 24 of the porous material 22 in the positive pressure regions 20.

The method may further include increasing the magnitude of the negative pressure (i.e., reducing the pressure relative to gauge pressure) in the negative pressure regions 40 and increasing the positive pressure in the positive pressure regions 20, wherein increasing the magnitude of both the negative and positive pressure decreases the magnitude of out-of-plane variations in the position of the bottom surface 16 of the thin substrate 12. The method may also include increasing or decreasing a difference between the positive pressure in the positive pressure regions 20 and the negative pressure in the negative pressure regions 40 to increase or decrease, respectively, the distance D between the upper surface 24 of the porous material 22 in the positive pressure regions 20 and the bottom surface 16 of the thin substrate 12.

The method may further include restricting lateral movement of the thin substrate 12 relative to the apparatus 10. In some embodiments, restricting lateral movement of the thin substrate 12 may include producing a gas barrier or an electrostatic barrier proximate a peripheral edge 18 of the thin substrate 12 to prevent lateral movement of the thin substrate 12 relative to the apparatus 10. In some embodiments, restricting lateral movement of the thin substrate 12 relative to the apparatus 10 may include positioning one or a plurality of physical barriers proximate the peripheral edges 18 of the thin substrate 12.

In some embodiments, the method may further include, introducing a reactive gas to the porous material 22 of the positive pressure regions 20, wherein contact of the reactive gas with the bottom surface 16 of the thin substrate 12 may cause a reaction of the reactive gas. Reaction of the reactive gas on contact with the bottom surface 16 of the thin substrate 12 may result in deposition of one or more compounds on the bottom surface 16 of the thin substrate 12.

The method may further include determining one or more properties of the thin substrate 12 held by the apparatus 10. In some embodiments, the method may include determining thickness or thickness variation at one or more positions on the top surface 14 of the thin substrate 12. The thickness or thickness variation may be determined by measuring a position of the top surface 14 of the thin substrate 12 as the bottom surface 16 is held at a constant position by the apparatus 10 to within a tolerance of less than or equal to 75 nm, less than or equal to 50 nm, less than or equal to 20 nm, less than or equal to 10 nm, less than or equal to 5 nm, less than or equal to 2 nm, or even less than or equal to 1 nm. The position of the top surface 14 of the thin substrate 12 may be measured using an interferometer or a high resolution microscope. The method may further include subjecting the thin substrate 12 held by the apparatus 10 to one or more processes. Processes may include photolithographic processes, chemical processes, inspection processes, or other processes. Chemical processes may include deposition processes, such as but not limited to chemical vapor deposition (CVD), physical vapor deposition (PVD), electrochemical vapor deposition (EVD), atomic vapor deposition (AVD), or other deposition processes; chemical etching; doping; annealing, or other processes.

The apparatuses 10 and methods disclosed herein may be utilized to hold thin substrates 12 during the manufacture, inspection, or otherwise processing of semiconductors. The apparatuses 10 and methods disclosed herein may also be used to hold thin substrates for manufacturing other electronic devices, such as batteries, LED screens, or other electronic devices. Other uses of the apparatuses and methods disclosed herein are contemplated.

While various embodiments of the apparatuses 10, 100 and methods of using the same have been described herein, it should be understood that it is contemplated that each of these embodiments and techniques may be used separately or in conjunction with one or more embodiments and techniques. It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

What is claimed is:

1. An apparatus for holding a thin substrate, the apparatus comprising:
a plurality of positive pressure regions comprising a porous material having an upper surface and a gas flowing outward from the upper surface, the gas producing a positive pressure above the upper surface in the positive pressure regions; and
a plurality of negative pressure regions interspersed with the plurality of positive pressure regions, the negative pressure regions exerting a holding force on a bottom surface of the thin substrate; and
wherein the negative pressure regions and the positive pressure regions are operable to maintain the bottom surface of the thin substrate a distance D from the upper surface of the porous material in the positive pressure regions.

2. The apparatus of claim 1, wherein no part of the apparatus contacts a top surface or the bottom surface of the thin substrate.

3. The apparatus of claim 1, wherein the apparatus is operable to maintain the bottom surface of the thin substrate flat to within a tolerance having a magnitude less than or equal to 75 nanometers (nm).

4. The apparatus of claim 1, comprising a pitch of less than or equal to 5 mm, wherein the pitch is measured from a center of a first positive pressure region to a center of a second positive pressure region that is closest to the first positive pressure region.

5. The apparatus of claim 1, wherein each of the plurality of negative pressure regions is disposed between two of the positive pressure regions.

6. The apparatus of claim 1, further comprising a negative pressure source fluidly coupled to the plurality of negative pressure regions, the negative pressure source operable to maintain each of the plurality of negative pressure regions at a pressure less than atmospheric pressure.

7. The apparatus of claim 6, wherein each of the plurality of negative pressure regions comprises the porous material and an impermeable coating applied to the upper surface of the porous material in each of the negative pressure regions, wherein each of the negative pressure regions is fluidly coupled to the negative pressure source through a passage passing through the porous material and the impermeable coating.

8. The apparatus of claim 1, wherein each of the plurality of negative pressure regions comprises:
a vacuum plenum having a surface recessed relative to the upper surface of the porous material in the positive pressure regions; and
a negative pressure source fluidly coupled to the vacuum plenum.

9. The apparatus of claim 8, wherein the negative pressure source is fluidly coupled to the vacuum plenum of each of the plurality of negative pressure regions by a passage or conduit.

10. The apparatus of claim 8, wherein the negative pressure source is directly fluidly coupled to the vacuum plenum of each of the plurality of negative pressure regions.

11. The apparatus of claim 1, comprising a plurality of preloaded gas bearings arranged in an array, wherein each of the preloaded gas bearings comprises a single positive pressure region and a single negative pressure region.

12. The apparatus of claim 1, wherein a pressure of the gas in the plurality of positive pressure regions is from 15 psia to 80 psia.

13. The apparatus of claim 1, wherein the gas is free of particulates, oil, and water.

14. The apparatus of claim 1, wherein the gas is a reactive gas that undergoes a chemical reaction upon discharge from the upper surface of the porous material or upon contacting the bottom surface of the thin substrate.

15. The apparatus of claim 1, further comprising at least one edge guide positioned to restrict lateral movement of the thin substrate in a plane parallel to the bottom surface of the thin substrate when the thin substrate is held by the apparatus.

16. The apparatus of claim 15, wherein the at least one edge guide comprises one or a plurality of physical barriers operable to restrict lateral movement of the thin substrate.

17. The apparatus of claim 15, wherein the at least one edge guide comprises an electrostatic barrier or a gas barrier operable to restrict lateral movement of the thin substrate.

18. A method of holding a thin substrate without contacting a bottom surface of the thin substrate, the method comprising:
positioning the thin substrate above an apparatus comprising:
a plurality of positive pressure regions comprising a porous material having an upper surface; and
a plurality of negative pressure regions interspersed with the plurality of positive pressure regions;
passing a gas into and through the porous material, wherein flow of the gas outward from the upper surface of the porous material produces a gas bearing between the upper surface of the porous material and the bottom surface of the thin substrate; and
applying a negative pressure to the plurality of negative pressure regions, the negative pressure exerting a holding force on the bottom surface of the thin substrate;
wherein a positive gas pressure in the positive pressure regions and the negative pressure in the negative pressure regions are operable to maintain the bottom surface of the thin substrate a distance D from the upper surface of the porous material in the positive pressure regions.

19. The method of claim 18, further comprising increasing a magnitude of the negative pressure and a magnitude of the positive pressure, wherein increasing the magnitude of both the negative and the positive pressure decreases a magnitude of out-of-plane variations in a position of the bottom surface of the thin substrate.

20. The method of claim 18, further comprising increasing or decreasing a difference between the positive gas pressure in the positive pressure regions and the negative pressure in the negative pressure regions to increase or decrease the distance D between the upper surface of the porous material in the positive pressure regions and the bottom surface of the thin substrate.

21. The method of claim 18, further comprising applying a gas bearing or electrostatic force proximate to an outer periphery of the thin substrate to prevent lateral movement of the thin substrate.

22. The method of claim 18, further comprising introducing a reactive gas to the porous material, wherein contact of the reactive gas with the bottom surface of the thin substrate causes reaction of the reactive gas.

23. The method of claim 22, wherein reaction of the reactive gas results in deposition of one or more compounds on the bottom surface of the thin substrate.

24. The method of claim 18, further comprising determining one or more of a thickness or a thickness variation of the thin substrate held by the apparatus.

25. The method of claim 18, further comprising subjecting the thin substrate to one or more processes while maintaining the thin substrate in position with the apparatus.
